(19) United States
(12) Patent Application Publication
(10) Pub. No.: US 2010/0084670 A1
(43) Pub. Date: Apr. 8, 2010

(54) LED CHIP WITH EXPANDED EFFECTIVE REFLECTION ANGLES

(75) Inventors: WEI-TAI CHENG, Guiren Shiang (TW); WEN-HAO SHIH, Huatan Township (TW)

Correspondence Address: Yen Jung Sung, 21-80 38 St, #C8, Astoria, NY, 11105, US

(73) Assignee: WEI-TAI CHENG, Guiren Shiang (TW)

(21) Appl. No.: 12/333,310

(22) Filed: Dec. 12, 2008

(30) Foreign Application Priority Data
Oct. 3, 2008 (TW) 097138290

(51) Int. Cl. H01L 33/00

(52) U.S. Cl. 257/98; 257/E33.068

(57) ABSTRACT

An LED chip with enhanced effective reflection angles is revealed, primarily comprising an epitaxial substrate, a first reflection mirror on the epitaxial substrate, a second reflection mirror, a light-emitting mechanism, and a first electrode. The first reflection mirror consists of a plurality of first DBRs with a first paired thickness. The second reflection mirror is formed on the first reflection mirror and consists of a plurality of second DBRs with a second paired thickness. Accordingly, two different ranges of effective reflection angles is provided to increase the effective reflection angles to overcome issues of lower production yield during the conventional thermally-bonding processes with reflection metal plates.

### FIELD OF THE INVENTION

The present invention relates to light-emitting semiconductor devices, and more particularly to LED chips with enhanced effective reflection angles.

### BACKGROUND OF THE INVENTION

LED chips are miniature light sources with high-efficient light emitters. However, the emitted light from the LED chips is omnidirectional so that half of the brightness is lost due to emitting toward chip bonding bottom, therefore, a reflection mechanism is necessary. There are two reflection mechanisms. One is to directly grow a plurality of DBRs (Distributed Bragg Reflectors) on an epitaxial substrate by repeatedly interlacing two layers having two different refractive indexes. However, even the required reflection mechanism can be achieved by a plurality of DBRs, the effective reflection angles are only 20 degrees leading to poor reflection efficiencies. The other is to remove the epitaxial substrate after wafer fabrication processes, followed by thermally bonding a reflection metal plate to enhance reflection efficiencies, however, the material of LED chips is semiconductor which is different from the reflection metal plate. Therefore, the thermally bonding processes need to be precisely controlled with critical parameters to avoid cracks at bonding interface leading to lower yield rates. The existing yield of bonding reflection metal plates is around 50% to 60% which is not cost effective nor environmental friendly.

As shown in FIG. 1, a prior art LED chip 100 primarily comprises an epitaxial substrate 110, a reflection mirror 120, and a light-emitting mechanism 140. The reflection mirror 120 is an interlacing combination consisting of a plurality of DBRs 121 repeatedly grown on the epitaxial substrate 110 by semiconductor wafer fabrication processes where each DBR 121 is a pair of epitaxial layers having different refractive indexes such as oxide, nitride, carbide, or fluoride. Meanwhile, the light-emitting mechanism 140 is formed on the reflection mirror 120 and is also manufactured by semiconductor wafer fabrication processes. Normally the light-emitting mechanism 140 comprises an N-type semiconductor layer 141, a P-type semiconductor layer 142, and a light-emitting layer 143 disposed between the two semiconductor layers 141 and 142. A transparent window layer 144 is formed over the P-type semiconductor layer 142. A first electrode 150 is disposed on the light-emitting mechanism 140 and a second electrode 170 is disposed on the bottom surface of the epitaxial substrate 110. The LED chip 100 is easy to fabricate and process. However, the reflection mirror 120 consisting of the plurality of DBRs 121 only has about 20 degrees of effective reflection angles leading to poor light reflection efficiencies.

As shown in FIG. 2, another prior art LED chip is proposed to improve the issue of poor light reflection efficiencies. The LED chip comprises a light-emitting mechanism 140 having the above described N-type semiconductor layer 141, P-type semiconductor layer 142, light-emitting layer 143, and window layer 144. The light-emitting mechanism 140 is formed on an epitaxial substrate by semiconductor wafer fabrication processes without DBR. After the semiconductor wafer fabrication processes, the epitaxial substrate is removed and then a reflection metal plate 180 is thermally bonded to the bottom surface of the light-emitting mechanism 140 to form a thermally-enhanced LED chip after singulation where the materials of the reflection metal plate 180 may be aluminum or gold or further has an aluminum layer or a gold layer plated on its surface to provide better light reflection. In order to ensure enough joint strength between the reflection metal plate 180 and the light-emitting layer 140, the bonding processes with critical parameters will easily cause damages to the light-emitting layer 140 leading to lower production yield.

### SUMMARY OF THE INVENTION

The main purpose of the present invention is to provide an LED chip with enhanced effective reflection angles and higher production yields.

According to the present invention, an LED chip with enhanced effective reflection angles is revealed, primarily comprising an epitaxial substrate, a first reflection mirror, a second reflection mirror, a light-emitting mechanism, and a first electrode. The first reflection mirror is formed on the epitaxial substrate by interlacing a plurality of first DBRs with a first paired thickness to provide a first range of effective reflection angles. The second reflection mirror is formed on top of the first reflection mirror by interlacing a plurality of second DBRs with a second paired thickness to provide a second range of effective reflection angles. The light emitting mechanism is formed on the second reflection mirror and the first electrode is formed on the light-emitting mechanism.

### DESCRIPTION OF THE DRAWINGS

FIG. 1 is a cross-sectional view of a prior art LED chip.

FIG. 2 is a cross-sectional view of another prior art LED chip.

FIG. 3 is a cross-sectional view of an LED chip with enhanced effective reflection angles according to the preferred embodiment of the present invention.

FIG. 4 is a cross-sectional view of the LED chip showing a light incident angle reflected at the reflection mirrors according to the preferred embodiment of the present invention.

FIG. 5 is a chart showing the effective reflection angles of the first reflection mirror in the LED chip according to the preferred embodiment of the present invention.

FIG. 6 is a chart showing the effective reflection angles of the second reflection mirror in the LED chip according to the preferred embodiment of the present invention.

FIG. 7 is a chart showing the effective reflection angles of the third reflection mirror in the LED chip according to the preferred embodiment of the present invention.

FIG. 8 is a chart showing the effective reflection angles of combination of the three reflection mirrors according to the preferred embodiment of the present invention.

FIG. 9 is a chart showing the effective reflection angles of combination of the first and second reflection mirrors according to the preferred embodiment of the present invention.

FIG. 10 is a chart showing the effective reflection angles of the combination of nine reflection mirrors according to the preferred embodiment of the present invention.

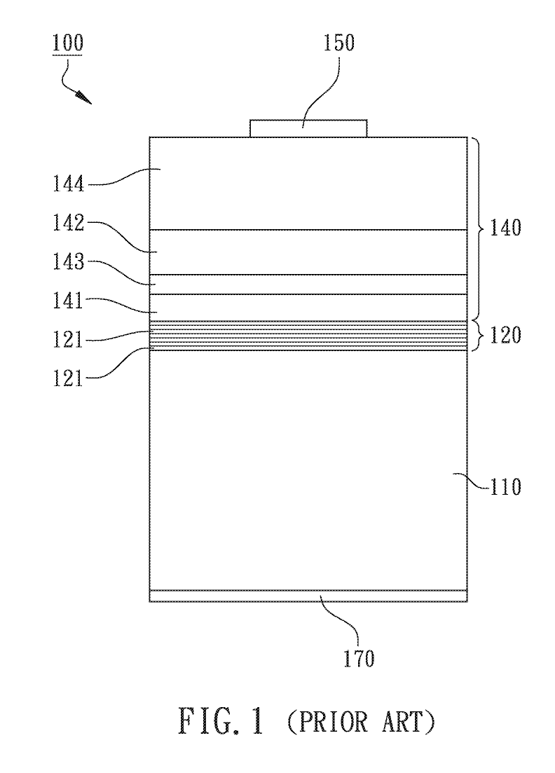

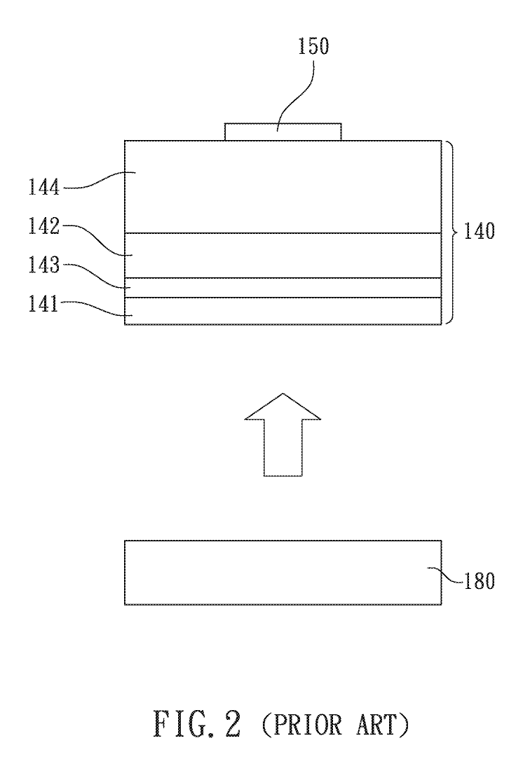

### DETAILED DESCRIPTION OF THE INVENTION

Please refer to the attached drawings, the present invention is described by means of embodiment(s) below.

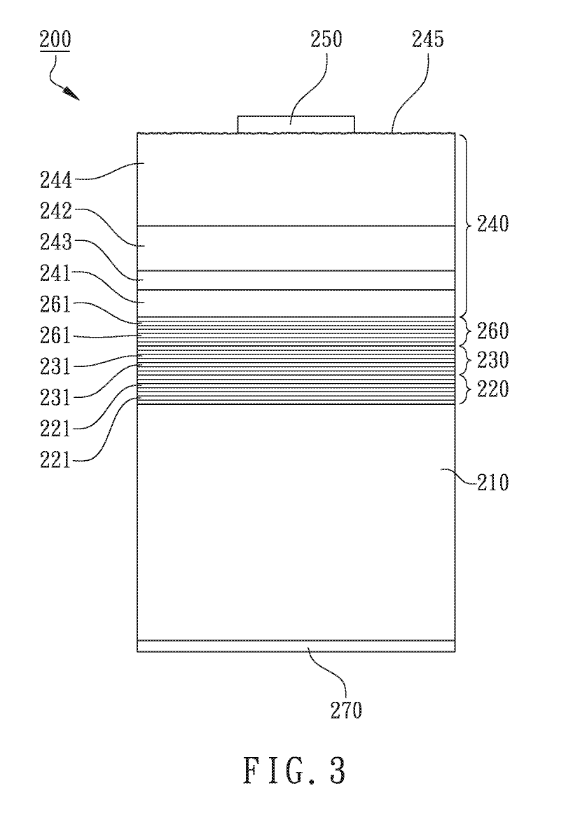

According to the preferred embodiment of the present invention, an LED chip is illustrated in a cross-sectional view of FIG. 3. The LED chip 200 primarily comprises an epitaxial substrate 210, a first reflection mirror 220, a second reflection mirror 230, a light emitting mechanism 240, and a first electrode 250 where the epitaxial substrate 210 is III-V semiconductors such as GaAs substrate. Since the epitaxial substrate 210 can absorb light, light emitting to the epitaxial substrate 210 should be avoided to reduce light loss. The first reflection mirror 220 and the second reflection mirror 230 are formed of a plurality of epitaxial layers by wafer manufacturing processes on the epitaxial substrate 210.

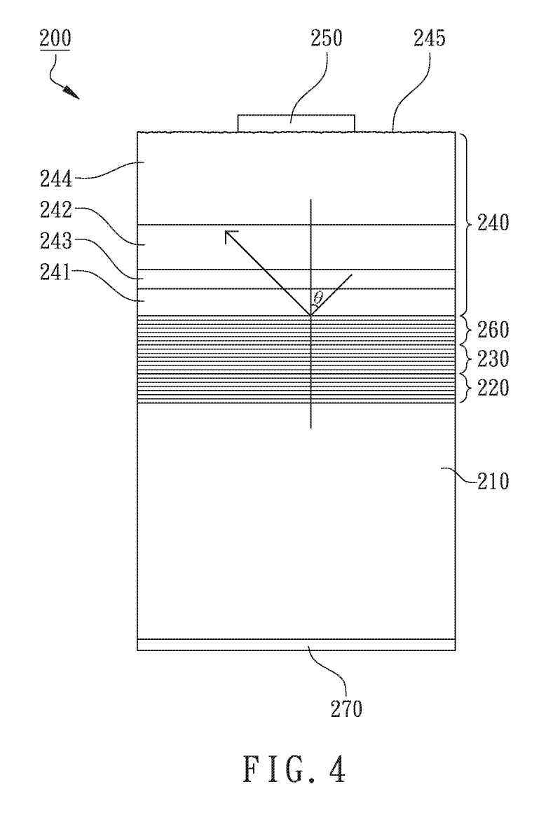

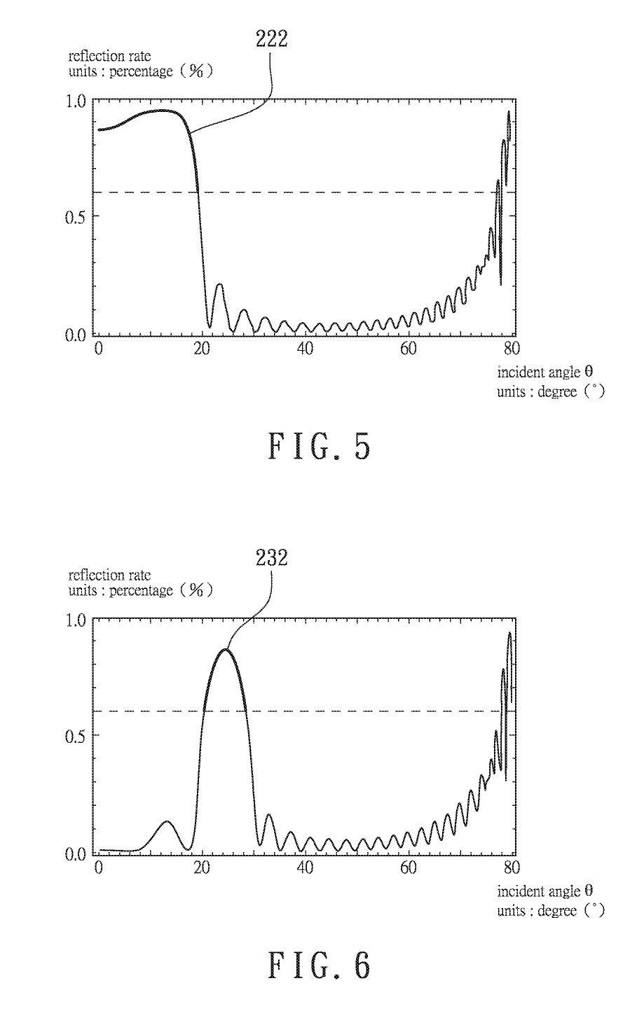

The first reflection mirror 220 is formed on the epitaxial substrate 210. The first reflection mirror 220 consists of a plurality of first DBRs 221 each having a first paired thickness to provide a first range 222 of effective reflection angles as shown in FIG. 5. Each first DBRs 221 is formed by interlacing a pair of epitaxial layers made of different materials with different refractive indexes such as AlAs, AlxGa1−xAs, or (AlxGa1−x)yIn1−yP, where x and y lie between 0 and 1. Normally the number of the first DBRs 221 ranges between from 15 to 25 where 18 to 20 are most common. The “effective reflection” is defined as more than 60% of incident light can be reflected by one reflection mirror, i.e., the reflection rates, where the reflection rates can be enhanced by increasing numbers of DBR layers. To be more specific, as shown in FIG. 5, the first range 222 of effective reflection angles has a specific region between 0 degree and 30 degrees. For example, when the incident angles ranging from 0 degree to 18 degrees emit to the first DBRs, more than 60% of the incident light can be reflected by the first reflection mirror 220 where the definition of the incident angle θ, as shown in FIG. 4, is the angle between the direction of the incident light and the perpendicular direction of the reflection mirror. When the incident angle θ is 0 degree, it means that the light is vertically emitted to the reflection mirrors 220, 230 and 260. There is no incident angle θ is 90 degrees, it means that the light is parallel to the reflection surface of the reflection mirrors 220, 230 and 260.

The second reflection mirror 230 is formed on the first reflection mirror 220. The second reflection mirror 230 consists of a plurality of second DBRs 231 with the second paired thickness to provide a second range 232 of effective reflection angles as shown in FIG. 6. The second range 232 of effective reflection angles is in a specific region between 15 degrees and 80 degrees. For example, as shown in FIG. 6, when the incident angle of light ranges between 20 degrees and 27.5 degrees, more than 60% of the incident light is reflected by the second reflection mirror 230. In this preferred embodiment, the first range 222 of effective reflection angles and the second range 232 of effective reflection angles do not overlap to expand the range of the effective reflection angles. Additionally, the light-emitted mechanism 240 is formed on the second reflection mirror 230 to emit light.

In one of the embodiments, the first DBRs 221 and the second DBRs 231 have the same ingredients and the first paired thickness and the second paired thickness are different. For example, the ingredients of the first DBRs 221 and the second DBRs 231 include Al or Ga. In a more specific embodiment, the ingredients and the compositions are the same. Each of the first DBRs 221 and the second DBRs 231 is formed by interlacing a pair of Al0.63Ga0.37As and AlAs where the effective reflection angle ranges can be changed by thickness adjustment of each DBR. In the present embodiment, the thickness of Al0.63Ga0.37As is around 46.3 nm and the thickness of AlAs is around 50.6 nm for each first DBR 221. The first paired thickness is 96.9 nm. The thickness of Al0.63Ga0.37As is around 50 nm and the thickness of AlAs is around 54.5 nm for each second DBR 231. The second paired thickness is 104.5 nm. In a more specific embodiment, when the wavelength of the incident light is 620 nm with only the first reflection mirror 220 formed from around 20 layers of the first DBRs 221, the first range 222 of effective reflection angles are from 0 degree to 20 degrees with a peak of reflection rate at around 12.5 degrees as shown in FIG. 5. When only with the second reflection mirror 230 formed by interlacing around 20 layers of the second DBRs 231, the second range 232 of the effective reflection angles are from 22 degrees to 27.5 degrees with a peak of reflection rate at around 25 degrees, as shown in FIG. 6. Therefore, the ranges of effective reflection angles can be adjusted by changing the paired thicknesses of the DBRs.

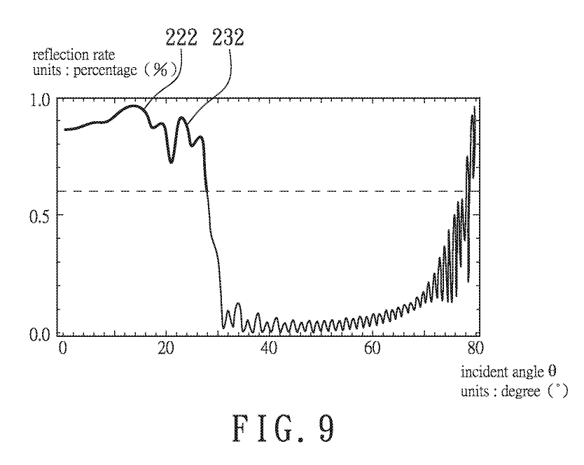

As shown in FIG. 8 and FIG. 9, when combined two or more reflection mirrors 220 and 230 with different ranges of effective reflection angles, the combined range of effective reflection angles can be effectively expanded such as from 0 degree to 27.5 degrees. Furthermore, the reflection range is amplified especially at the boundary region of two adjacent ranges of effective reflection angles from different reflection mirrors. Accordingly, the first range 222 and the second range 232 of the effective reflection angles are not overlapped to effectively expand the range of effective reflection angles. The amplitude differences between two ranges of effective reflection angles can be effectively reduced. In the present embodiment, the reflection rate of the first reflection mirror 220 dramatically drops to 20% (as shown in FIG. 5) when the incident light ranges between 20 degrees and 22 degrees. But the reflection rate of the second reflection mirror 230 is dramatically increased from 20% up to 60% (as shown in FIG. 6) when the incident light ranges between 24 degrees and 26 degrees. When the first reflection mirror 220 is combined with the second mirror 230, the reflection rate of the incident angles ranged between 20 degrees and 24 degrees is maintained more than 60%, as shown in FIG. 9, to effectively reduce light loss.

In another equivalent embodiment, the first DBRs 221 and the second DBRs 231 have the same ingredients but with different compositions. For example, the ingredients of the first DBRs 221 and the second DBRs 231 can be demonstrated by using the combination of AlxGa1−xAs and AlAs. In the first modified embodiment, each of the first DBRs 221 is formed by interlacing a layer of Al0.3Ga0.7As and a layer of AlAs where the thickness of Al0.3Ga0.7As is around 43 nm and the thickness of AlAs is around 50.5 nm so that the first reflection mirror 220 has a peak of reflection rate at around 12.5 degrees as shown in FIG. 5. The first paired thickness is 93.5 nm. Moreover, each of the second DBRs 231 is formed by interlacing a layer of Al0.63Ga0.37As and a layer of AlAs where the thickness of Al0.63Ga0.37As is around 49.9 nm and the thickness of AlAs is around 54.4 nm so that the second reflection mirror 220 has a peak of reflection rate at around 25 degrees as shown in FIG. 6. The second paired thickness is 104.3 nm. The combination of the first reflection mirror 220 and the second reflection mirror 230 can effectively expand the effective reflection ranges as the same as shown in FIG. 9. Moreover, when the DBRs consisting of pairs of Al0.3Ga0.7As and AlAs with higher light absorption rates are regarded as the first reflection mirror 220 to dispose at the bottom layer of the combined assemblies, i.e., adjacent to the epitaxial substrate 210, the light loss can be reduced.

In the second modified embodiment, the ingredients and the compositions of the first DBRs 221 and the second DBRs 231 can be the same as the ones in the first modified embodiment mentioned above. However, the paired thickness of the first DBRs 221 and the second DBRs 231 can be adjusted to change the range of effective reflection angles. Each of the first DBRs 221 is a paired combination of a layer of Al0.3Ga0.7As and a layer of AlAs where the thickness of Al0.3Ga0.7As is around 46.3 nm and the thickness of AlAs is around 54.4 nm, and then the first reflection mirror 220 has a peak of reflection rate around 25 degrees because that the first paired thickness is 100.7 nm. Moreover, each of the second DBRs 231 is a paired combination of a layer of Al0.63Ga0.37As and a layer of AlAs where the thickness of Al0.63Ga0.37As is around 46.3 nm and the thickness of AlAs is around 50.5 nm, and then the second reflection mirror 230 has a peak of reflection rate around 12.5 degrees because that the second paired thickness is 96.8 nm. Preferably, the light absorption rate of the second reflection mirror 230 is smaller than the one of the first reflection mirror 220.

The light-emitting mechanism 240 includes an N-type semiconductor layer 241, a P-type semiconductor layer 242, and a light-emitting layer 243 disposed between the N-type semiconductor 241 and the P-type semiconductor 242. The semiconductor layers 241 and 242 are made of AlInP. The light-emitting layer 243 is a multi-quantum well made of (AlxGa1−x)yIn1−yP where x and y range between 0 and 1 to manufacture a high brightness LED. In the present embodiment, the P-type semiconductor layer 242 is relatively more adjacent to the first electrode 250 than the N-type semiconductor layer 241. In this embodiment, the light-emitting mechanism 240 further includes a window layer 244 disposed between the P-type semiconductor layer 242 and the first electrode 250 where the window layer 244 is transparent and is made of GaP. The purpose of the window 244 is to increase light output. Preferably, the window layer 244 has an external surface 245 which is a rough surface exposed to atmosphere to increase angles of light output and to increase light emitting efficiency by avoiding reflection of the emitting light at the window layer 244 back to the LED chip 200.

The first electrode 250 is formed on the light-emitting mechanism 240. The LED chip 200 further comprises a second electrode 270 formed at the bottom of the epitaxial substrate 210. According to different products, the second electrode can be formed at the extrusion portion of the N-type semiconductor layer 241 of the light-emitting mechanism 240, not shown in the figure. The first electrode 250 can be made of Au or AuBe and the second electrode 270 can be made of Au or AuGe.

Therefore, the first reflection mirror 220, the second reflection mirror 230, the light-emitting mechanism 240, and the first electrode 250 can be fabricated by the semiconductor wafer fabrication processes on the epitaxial substrate 210 without the issue of the low production yield by conventionally thermally bonding process of reflection metal plate. Additionally, the range of effective reflection angles and the light-emitting efficiency are effectively increased.

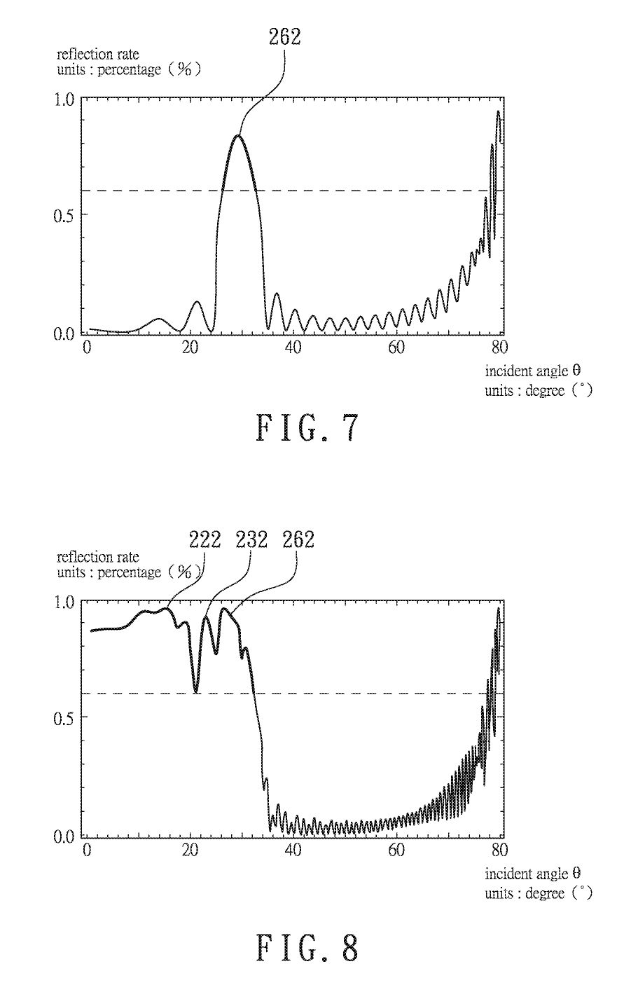

Furthermore, in the present embodiment, the LED chip 200 further comprises at least a third reflection mirror 260 disposed between the second reflection mirror 230 and the light-emitting mechanism 240 wherein the third reflection mirror 260 consists of a plurality of third DBRs 261. Each third DBR 261 has a third paired thickness to provide a third range of effective reflection angles. In the present embodiment, the third range 262 of effective reflection angles is located in a specific region between 20 degrees and 75 degrees. For example, as shown in FIG. 7, when the incident angle θ is between 26 degrees and 34 degrees, more than 60% of the incident light is reflected by the third reflection mirror 260. The third DBRs 261 have the same ingredients and compositions but with different thicknesses with the second DBRs 231, such as each of the third DBRs 261 is formed by interlacing a layer of Al0.63Ga0.37As and a layer of AlAs. In the present embodiment, the thickness of Al0.63Ga0.37As is 52.2 nm and the thickness of AlAs is 56.9 nm. The third paired thickness is 109.1 nm. Accordingly, the third paired thickness is much larger than the first paired thickness of the first DBRs 221 and the second paired thickness of the second DBRs 231. In a more specific embodiment, when the wavelength of the incident light is 620 nm with only the third reflection mirror 260, the third range 262 of effective reflection angles is from 26 degrees to 34 degrees with a peak of reflection rate at around 30 degrees as shown in FIG. 7. As shown in FIG. 8, when the LED chip 200 is assembled with the first reflection mirror 220, the second reflection mirror 230, and the third reflection mirror 260, the combined range of effective reflection angles can be expanded from 0 degree to 34 degrees. After confirmation by experiments, when the LED chip 200 is assembled with the first reflection mirror 220 and the second reflection mirror 230, but without the third reflection mirror 260, the light-emitting efficiency is 1.18 times more than a conventional LED chip with only one kind of DBRs. However, when the LED chip 200 is assembled with the first reflection mirror 220, the second reflection mirror 230, and the third reflection mirror 260, the light-emitting efficiency is 1.3 times more than a conventional LED chip with only one kind of DBRs.

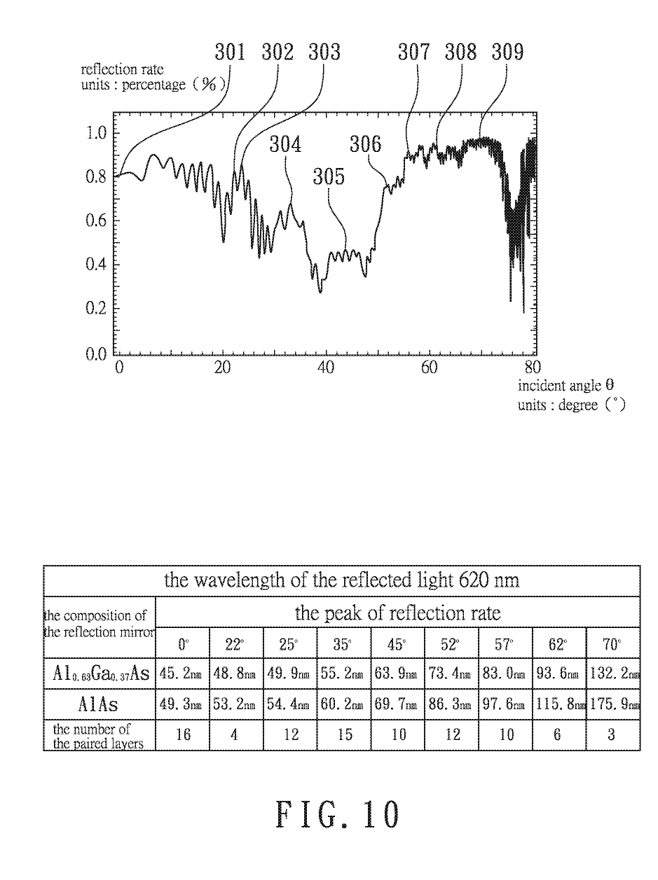

The numbers of reflection mirrors, the thicknesses of the DBRs inside the reflection mirrors, and the layers of pairs are not limited in the present invention. In a more specific embodiment, an LED chip can have nine reflection mirrors with different paired thickness to generate different peaks from 301 to 309 of reflection rates as shown in FIG. 10. The ingredients and compositions of the DBRs of nine different reflection mirrors can be the same such as each DBR of the nine different reflection mirrors is made of Al0.63Ga0.37As and AlAs but with different layers of pairs and different paired thicknesses. When the thicknesses of the DBRs increase, the peaks of the reflection rates can be shifted to higher incident angles to compose a nearly complete reflection assembly of reflection mirrors.

Furthermore, preferably, the LED chip in the present invention, the reflection mirrors on the most top layer away from the epitaxial substrate 210 have appropriately designed DBRs to reduce light absorption rates. The materials of the DBRs of the reflection mirrors on the most top layer should meet the formula of “Eg is not less than Eλ” where Eg is the energy bandgap, equal to the energy differences between the conduction band and the valence band. Eλ is the radiation energy within the wavelength range of an incident light radiated from the light-emitting mechanism which can be chosen by calculation. When the wavelength of incident light is 621 nm, for example, Eλ is 2.0 eV where Eg of AlAs is 2.95 eV. The equation of Eg(x) of AlxGa1−xAs is 1.420+1.087x+0.428x2 (eV). Therefore, when x is equal to 0.63, then Eg of Al0.3Ga0.7As is 2.27 eV which is greater than Eλ of 2.0 eV. Moreover, Eg of AlAs is also greater than Eλ of 2.0 eV where both Eg have met the requirements of “Eg is not less than Eλ”. Therefore, the combination of Al0.3Ga0.7As and AlAs can be implemented as the DBRs on the most top of the reflection mirrors to reduce light absorption rates and heat dissipation. On the contrary, when x is equal to 0.3, then Eg of Al0.3Ga0.7As is 1.79 eV which is less than Eλ of 2.0 eV. Therefore, the combination of Al0.3Ga0.7As and AlAs is improper to implement as the DBRs on the most top of the reflection mirrors of the present invention.

The above description of embodiments of this invention is intended to be illustrative but not limiting. Other embodiments of this invention will be obvious to those skilled in the art in view of the above disclosure.

What is claimed is:

1. An LED chip primarily comprising:
an epitaxial substrate;
a first reflection mirror formed on the epitaxial substrate and consisting of a plurality of first DBRs with a first paired thickness to provide a first range of effective reflection angles;
a second reflection mirror formed on the first reflection mirror and consisting of a plurality of second DBRs with a second paired thickness to provide a second range of effective reflection angles;
a light-emitting mechanism formed on the second reflection mirror; and
a first electrode formed on the light-emitting mechanism.

2. The LED chip as claimed in claim 1, wherein the first DBRs and the second DBRs have the same ingredients and the first paired thickness and the second paired thickness are different.

3. The LED chip as claimed in claim 2, wherein the ingredients of the first DBRs and the second second DBRs include Al or Ga.

4. The LED chip as claimed in claim 1, wherein the first DBRs and the second DBRs have the same ingredients but with different compositions.

5. The LED chip as claimed in claim 1, wherein the first range of effective reflection angles and the second range of effective reflection angles are adjacent each other without overlapping.

6. The LED chip as claimed in claim 5, wherein the first range of effective reflection angles has a specific region between 0 degree to 30 degrees and the second range of effective reflection angles has a specific region between 15 degree and 80 degrees.

7. The LED chip as claimed in claim 1, further comprising at least a third reflection mirror disposed between the second reflection mirror and the light-emitting mechanism, wherein the third reflection mirror consists of a plurality of third DBRs with third paired thickness to provide a third range of effective reflection angles.

8. The LED chip as claimed in claim 7, wherein the third DBRs and the second DBRs have the same ingredients and compositions and the third paired thickness and the second paired thickness are different.

9. The LED chip as claimed in claim 1, further comprising a second electrode formed on a bottom surface of the epitaxial substrate.

10. The LED chip as claimed in claim 1, wherein the light-emitting mechanism includes an N-type semiconductor layer, a P-type semiconductor layer, and a light-emitting layer disposed between the N-type semiconductor layer and the P-type semiconductor layer.

11. The LED chip as claimed in claim 10, wherein the P-type semiconductor layer is more adjacent to the first electrode than the N-type semiconductor layer, wherein the light-emitting mechanism further comprises a window layer disposed between the P-type semiconductor layer and the first electrode.

12. The LED chip as claimed in claim 11, wherein the window layer has a rough exposed surface.

13. The LED chip as claimed in claim 1, wherein a light absorption rate of the second reflection mirror is smaller than the one of the first reflection mirror.

14. An LED chip comprising a plurality of reflection mirrors disposed between a epitaxial substrate and a light-emitting mechanism, each reflection mirror consisting of a plurality of DBRs with a paired thickness to provide a combination of a plurality of ranges of effective reflection angles, wherein the materials of the DBRs of the reflection mirrors meet the formula of “Eg is not less than Eλ” where Eg is the energy bandgap equal to the energy differences between the conduction band and the valence band and Eλ is the radiation energy within the wavelength range of an incident light radiated from the light-emitting mechanism.

15. The LED chip as claimed in claim 14, wherein each DBR of the topmost one of the reflection mirrors is composed by the combination of Al0.3Ga0.7As and AlAs.
